(19) United States
(12) Patent Application Publication
(10) Pub. No.: US 2008/0116878 A1
(43) Pub. Date: May 22, 2008

(54) Power sensor with switched-in filter path

(75) Inventor: Dean B. Nicholson, Windsor, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 11/553,467

(22) Filed: Oct. 27, 2006

(51) Int. Cl. G01R 23/04

(52) U.S. Cl. 324/95

(57) ABSTRACT

An RF power sensor is enclosed within a housing. An input port of the housing brings an RF signal into the housing. An RF switch within the housing switches the RF signal between an amplified and filtered path, a through-path and an attenuated path. An RF power detector within the housing detects the electric field of the RF signal and rectifies it into a current to measure the RF energy of the RF signal passing through the amplified path, through-path or attenuated path.

### BACKGROUND OF THE INVENTION

The two most common types of power sensors can be classified as thermal-based power sensors (for example thermocouple and thermistor power sensors) and current-rectification based power sensors.

Rectification-based power sensors include diode sensors such as low-barrier Schottky diodes and PDB diodes. The electric field of the input RF signal generates an AC voltage across the diode and this AC voltage is rectified by the diode into a DC voltage. This DC voltage is related to the power of the input RF signal.

Prior-art techniques using diode-based power sensors to measure powers below −70 dBm rely on constantly re-zeroing the meter/sensor, which requires time consuming averaging for the zeroing, as well as for the subsequent measurements at these low power levels. These techniques are also not very stable as the temperature drifts over time, changing the RF noise power into the sensor integrated over frequency, as well as the leakage currents of the amplifiers and circuitry following the sensor, and only provide power measurements down to power levels of approximately −75 dBm.

Signal analyzers or spectrum analyzers are used to measure signals having power levels below −70 dBm, but they are three to five times more expensive than power sensors/meters and are physically larger.

It would be desirable to provide a diode-based power sensor to replace the spectrum analyzers used for prior-art low-power measurements. Additionally, it would be desirable to provide a diode-based power sensor to accurately, quickly and cheaply measure power levels which are at least 20 dBm to 30 dBm below the −70 dBm low power limit of prior-art diode-based power sensors.

### SUMMARY OF THE INVENTION

The present invention provides a rectification-based power sensor for measuring power levels down to as low as −90 dBm, −100 dBm or even lower.

In more general terms the invention is an RF rectification-based power sensor including an enclosing housing. An input port of the housing brings an RF signal into the housing. An RF switch within the housing switches the RF signal between an amplified and filtered path, a through-path and an attenuated path. An RF power detector within the housing detects the electric field of the RF signal and rectifies it into a current to measure the RF energy of the RF signal passing through the amplified path, through-path or attenuated path.

### BRIEF DESCRIPTION OF THE DRAWINGS

Further preferred features of the invention will now be described for the sake of example only with reference to the following figure, in which:

FIG. 1 shows the power sensor with switched-in amplifier and filter path of the present invention.

### DETAILED DESCRIPTION

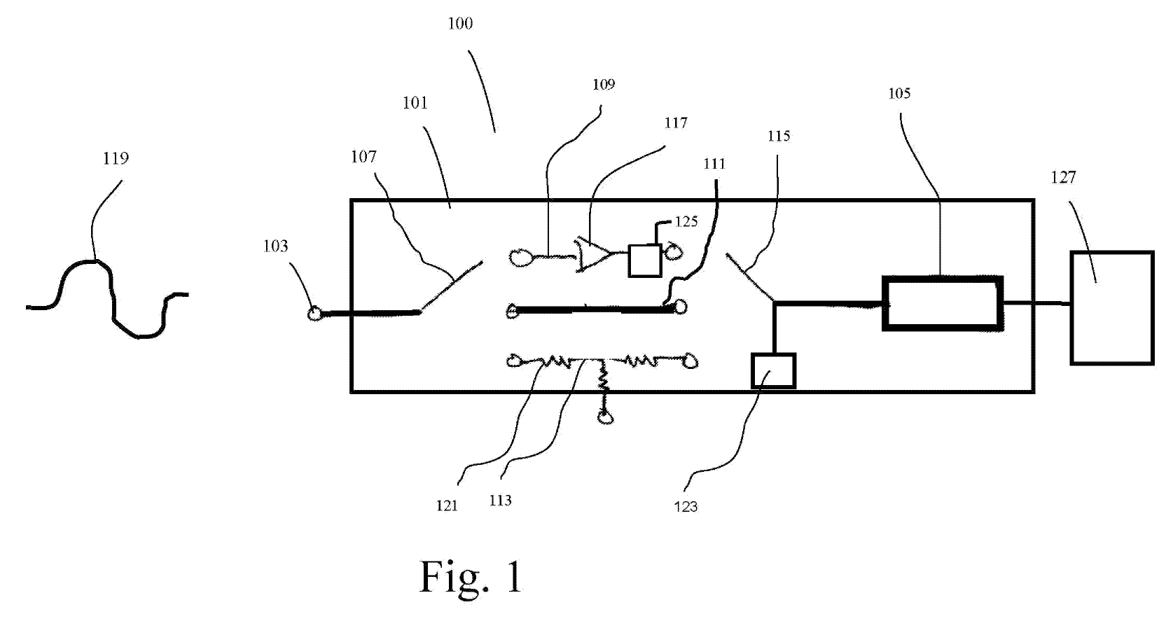

FIG. 1 shows an RF power sensor 100 which includes an enclosing housing 101. An input port 103 of the housing brings an RF signal 119 into the housing. The RF frequency range is considered to cover frequencies from approximately 150 kHz up to the IR range, though recent improvements in DC blocking capacitors have allowed these RF techniques to be extended down to below 10 kHz in many applications. In other embodiments the frequency can be limited to the microwave frequency range of 1 GHz and higher or the frequency can be limited to the optical range. The transmission media used can be cable, waveguide, or other media.

An RF power detector 105 is within the housing 101. The RF power detector 105 can be a rectification-based power detector such as a diode detector, thereby making the RF power sensor 100 a rectification-based RF power sensor which can be a diode-based RF power sensor. The diode detector can be a low-barrier Schottky diode detector or a PDB diode detector, for example. The rectification-based power detectors convert the AC electric field of an input RF signal into a DC quantity. More particularly, when the power detector is a diode-based power detector, the electric field of the input RF signal generates an AC voltage across the diode and this AC voltage is rectified by the diode into a DC voltage. This DC voltage is related to the power of the input RF signal. Other types of power measurement detectors can also be used.

Within the housing 101 of the RF power sensor 100 are three different paths through which the RF signal 119 can travel to the RF power detector 105.

The three paths are: a filtered and amplified path 109 including a solid-state amplifier 117 and a filter 125 through which the RF signal 119 is amplified, filtered and passed to the RF power detector 105; a through-path 111 through which the RF signal 119 is passed to the RF power detector 105; and an attenuation-path 113 including an RF attenuator 121 (for example a resistor or multiple resistors) through which the RF signal 119 is attenuated and passed to the RF power detector 105. In other embodiments two paths can be used or more than three paths can be used.

The filtered and amplified path 109 can include one or more solid-state amplifiers 117 for amplifying the RF signal 119 and one or more filters 125 for filtering the amplified RF signal. In other embodiments the amplifiers 117 can be of types other than solid-state amplifiers. The amplifier can be a low-noise amplifier having a gain of approximately 45 dB, for example. The amplifier 117 can have it's gain calibrated and corrected over frequency and temperature to maintain accuracy. The filter 125 can be a tunable filter and can have a loss of approximately 5 dB, for example. The combined amplification and loss are such as to amplify the signal to a power level allowing the detector 105 operate in it's square-law region.

In an exemplary embodiment, the RF signal 119 through the first filtered and amplified path 109 has a power level in the range of approximately −100 dBm to −60 dBm. The 45 dB gain of the amplifier 117 and 5 dB loss of the filter 125 results in a net gain of 40 dB which amplifies the low power level signal to a range of between approximately −60 dBm to −20 dBm, allowing the detector 105 to operate in it's square-law region.

If the filter 125 were excluded from the filtered and amplified path 109, then the entire broadband noise floor would be raised by 45 dB, the gain of the amplifier 117.

Without gain, the noise power (Pn) is:

Pn=k*T*BW

where Pn is power in watts, k is Boltzmann's constant (1.38×10⁻²³ J/K), T is the temperature in Kelvin (K) and BW is the bandwidth in Hertz. In the RF power detector 105, the bandwidth BW can be 20 GHz.

The result for the noise power is Pn=−71 dBm at a temperature of 290 K, which is already at the level of the low level signals to be measured.

Averaging the sensor DC output signal over time with no RF input signal applied to the sensor, then subtracting out this DC voltage will effectively “zero” out the integrated thermal RF noise integrated over frequency, as well as “zeroing” out the effect of the amplifiers and other associated electronic circuitry following the sensor. However, these “zeroing” techniques are slow to perform, and lose their accuracy as the temperature changes over time, with the changing temperature changing the broadband RF noise input to the sensor as well as the noise and leakage current contributions of the amplifiers and other circuitry following the sensor which are also temperature dependent.

The addition of the filter 125 following the amplifier 117, lowers the broadband noise power in the regions outside of the filter's bandwidth. For example, if the filter 125 is a band-pass filter having BW=10 MHz, then the noise power is Pn=−104 dBm at a temperature of 290 K. This is below the minimum signal to be detected.

The lowering of the noise floor by the filter 125 is most effective over a broadband frequency range if the filter 125 is terminated in a low impedance element such as a capacitor. Also, the filter 125 is more effective if the filter 125 is located very close to the sensor 105, for example within a distance approximately 1/10 of the wavelength of the sensor's highest frequency of operation. The reason for using this small distance is that although a bandpass, lowpass or highpass filter placed in front of the sensor 105 will greatly reduce the amplified thermal noise coming into the sensor 105 from the output of the amplifier 117 through the transmission line, the sensor 105 itself will also emit broadband thermal noise in the RF spectrum. This thermal noise will travel outward from the sensor 105, travel down the transmission line and will be reflected back to the sensor 105 by any discontinuity such as a low impedance. Thus, the reflection of sensor thermal noise from the filter 125 terminated by a low impedance element can raise the noise floor.

However, if there is a low pass, bandpass, or highpass filter that is terminated in a low impedance element and that is very close to the sensor (less than approximately 1/10 of a wavelength), then this will effectively short out the RF power being emitted by the sensor outside the bandwidth of the filter 125, and the noise contribution from the region outside of the filter pass band will be effectively zero.

The reason that the value of 1/10 of a wavelength is chosen as a figure of merit for a maximum distance between the filter 125 and the power sensor 105 in order to be effective is that a short circuit ¼ of a wavelength away from the reference point becomes an open circuit, which effectively reflects back the outward going power in-phase with the emitted power from the sensor, which would not decrease the measured noise level. Thus, 1/10 of a wavelength is sufficiently smaller than ¼ of a wavelength so that a low impedance placed at this distance from the sensor will still look like a short circuit to the sensor 105.

Even if the filter 125 is not placed physically near to the sensor 105, however, it will still highly attenuate the amplified broadband noise outside the passband of the filter 125, and no matter what phase the thermal noise emitted by the sensor 105 is reflected back to the sensor 105, it will still be near the thermal noise floor, and simply increasing the gain of the amplifier will increase the strength of the signal in the desired frequency range sufficiently above the integrated thermal noise to the sensor outside the filter bandwidth, allowing an accurate measurement to be made.

The filter 125 can be implemented by switching between multiple fixed or tunable filters with compact, high performance RF switches such as MEMs or FET switches, and this lowers the broadband noise floor by 20 to 30 dB or more, allowing the desired low level signals to be measured accurately and quickly. Since the signal levels in this amplified and filtered path are relatively low in power, there need not be stringent requirements on the distortion performance of the switches in this attenuated path. In one embodiment, a low-pass filter can be included for switching in at frequencies below 1 GHz to limit the excess noise bandwidth so that a large number of band-pass filters are not needed to cover this range. A filter switch is used to switch between multiple filters. The filter switch can be implemented using different types of switches such as compact MEMS switches or solid state switches to provide tunable band-pass filters. Fixed frequency low-pass filters, band-pass filters or high-pass filters can also be used for the region below 1 GHz or other selected regions of interest.

A first switch 107 is also within the housing 101 and has three separate positions corresponding to the three different paths 109, 111, 113 through which the RF signal 119 can travel.

A second switch 115 is within the housing 101 and also has three separate positions corresponding to the three different paths through which the RF signal 119 can travel.

The first and second switches 107, 115 are in a first position wherein they direct the RF signal 119 through the first filtered and amplified path 109 when the RF signal has a low power level in the range of approximately −100 dBm to −60 dBm. The gain of the first filtered and amplified path 109 allows the detector 105 to operate in it's square-law region.

The first and second switches 107, 115 are in a second position wherein they direct the RF signal 119 through the second through-path 111 when the RF signal has a medium power level of between approximately −50 dBm or −60 dBm and −20 dBm. Again allowing the detector 105 operate in it's square-law region.

The first and second switches 107, 115 are in a third position wherein they direct the RF signal 119 through the third attenuation path 113 including an RF attenuator 121 when the RF signal has a power level between approximately −20 dBm and +30 dBm. The attenuation path 113 can include one or more attenuators 121 of different values with switches to select between them, or a distributed attenuator for attenuating the RF signal 119. The value of the attenuation can be up to or greater than 50 dB, allowing the detector 105 to operate in it's square-law region. Multiple attenuation settings would be valuable so that the signal level is not too close to −70 dBm, which is the noise floor of the sensor where measurements are slower due to needing multiple averages, and also less accurate.

Thus, the attenuation path 113 can be comprised of multiple switched attenuator sections having different values. A power distributor, such a power divider, power splitter or directional coupler can be used for distributing the RF signal 119 to multiple attenuator paths when the first and second switches are in the third positions and wherein different combinations of the attenuator path outputs are switched between to select a desired attenuation amount. The power distributor can also be comprised of power dividers integrated into a single IC.

The first and second switches 107, 115 can be selected from many different types of switches such as MEMS switches or solid state switches. Preferably the switch is a switch with low distortion.

The switch 115 is under the control of a processor 123 which can be part of the RF power sensor 100 or can be part of a power meter 127, for example. The control of the switching to determine which path 109, 111, 113 is selected for the RF signal 119 to go through can be made, for example, by the power meter 127 following the sensor using the processor 123. The power meter 127 knows the present path selected and the present power level being read, and can determine if the present selected path is the proper one for the measurement, or if a different path should be selected. As an example, if the attenuated path 113 has been selected, and no RF signal, or an RF signal near the noise floor of the sensor is being read, then the power meter 127 changes the switches to configure the measurement to be made with the thru path 111. If the new power meter reading with the thru path 111 is still at or near the noise floor of the sensor, then the power meter 127 would reconfigure the sensor switches to select the amplified and filtered path 109. Extensions and further examples of this technique for selecting how to control the switches for the power sensor are straightforward, and will not be given here.

In the foregoing specification, the invention has been described with reference to specific exemplary embodiments thereof. The specification and drawings are, accordingly, to be regarded in an illustrative sense rather than a restrictive sense.

1. An RF rectification-based power sensor including an enclosing housing comprising:
an input port of the housing for bringing an RF signal into the housing;
an RF rectification-based power detector within the housing;
a first switch within the housing, which switches between a first position when the RF signal has a power level of less than approximately −60 dBm, a second position when the RF signal has a power level of between approximately −60 dBm and −20 dBm and a third position when the RF signal has a power level between approximately −20 dBm and +30 dBm.;
a second switch within the housing which switches between a first position, a second position and a third position;
an amplified and filtered path including a solid-state amplifier and a filter through which the RF signal is amplified, filtered and passed to the RF power detector when the first and second switches are in the first positions;
a through-path through which the RF signal is passed to the RF power detector when the first and second switches are in the second positions; and
an attenuation path including an RF attenuator through which the RF signal is attenuated and passed to the RF power detector when the first and second switches are in the third positions.

2. An RF power sensor comprising:
a housing;
an input port of the housing for bringing an RF signal into the housing;
an RF switch within the housing for switching the RF signal between an amplified and filtered path and another non-amplified path; and
an RF power detector within the housing for measuring RF power output from the amplified and filtered path.

3. The power sensor of claim 2, wherein the RF power detector is an RF rectification-based power detector.

4. The power sensor of claim 2, wherein the amplified and filtered path includes a tunable filter.

5. The power sensor of claim 2, further comprising a second switch for switching between the amplified and filtered path to direct an amplified RF signal to the RF power detector and the non-amplified path to direct a non-amplified signal to the RF power detector.

6. The power sensor of claim 2, wherein the amplified and filtered path includes a solid-state amplifier.

7. The power sensor of claim 6, wherein the solid-state amplifier has a gain of approximately +45 dB and the filtering inserts a loss of approximately +5 dB.

8. The power sensor of claim 2, wherein the non-amplified path is an attenuation-path including an RF attenuator.

9. The power sensor of claim 5, further comprising an attenuation-path including an RF attenuator and wherein the non-amplified path is a through-path.

10. The power sensor of claim 9, wherein the second switch is for switching between the amplified and filtered path, through-path and attenuation-path.

11. The power sensor of claim 2, wherein the amplified and filtered path includes a filter switch for switching between multiple band-pass filters.

12. The power sensor of claim 11, wherein the amplified and filtered path includes a low-pass filter for switching in at low frequencies.

13. The power sensor of claim 10, wherein the RF switch within the housing switches the RF signal to the amplified path when the RF signal received by the input port has a power level of less than approximately −60 dBm.

14. The power sensor of claim 10, wherein the RF switch within the housing switches the RF signal to the through-path when the RF signal received by the input port has a power level of between approximately −60 dBm and −20 dBm.

15. The power sensor of claim 10, wherein the RF switch within the housing switches the RF signal to the attenuation-path when the RF signal received by the input port has a power level between approximately −20 dBm and +30 dBm.

16. The power sensor of claim 2, wherein the RF switch is a MEMS switch.

17. The power sensor of claim 2, wherein the RF switch is a solid state switch.

18. The power sensor of claim 11, wherein the filter switch is a MEMS switch.

19. The power sensor of claim 11, wherein the filter switch is a solid state switch.

20. The power sensor of claim 2, wherein the RF power detector is diode detector.

21. The power sensor of claim 8, wherein the attenuation path is comprised of multiple switched attenuator sections having different values.

22. The power sensor of claim 8, further comprising a power distributor for distributing the RF signal to multiple attenuator paths when the first and second switches are in the third positions and wherein different combinations of the attenuator path outputs are switched between to select a desired attenuation amount.

23. The power sensor of claim 22, wherein the power distributor is selected from the set consisting of: a power splitter, a power divider and a directional coupler.

24. The power sensor of claim 22, wherein the power distributor is comprised of power dividers integrated into a single IC.
